(19) United States
(12) Patent Application Publication
(10) Pub. No.: US 2001/0016292 A1
(43) Pub. Date: Aug. 23, 2001

(54) Electron beam mask, production method thereof, and exposure method

(76) Inventors: Hideo Kobinata, Tokyo (JP); Hiroshi Yamashita, Tokyo (JP)

Correspondence Address: Paul J. Esatto, Jr., Scully, Scott, Murphy & Presser, 400 Garden City Plaza, Garden City, NY, 11530, US

(21) Appl. No.: 09/749,235

(22) Filed: Dec. 27, 2000

(30) Foreign Application Priority Data
Dec. 27, 1999 (JP) 11-368719

(51) Int. Cl. G03F 9/00; G03C 5/00; G03F 1/00

(52) U.S. Cl. 430/5; 430/296

(57) ABSTRACT

The present invention provides an electron beam mask having a plurality of apertures according to a predetermined design pattern for use in a batch projection exposure by an electron beam. At least one of the apertures which requires reinforcement such as those having a doughnut shape or a bridged doughnut (leaf) shape is selectively filled with a thin film made from a material transmitting the electron beam.

### BACKGROUND OF THE INVENTION

1. Field of the Invention

The present invention relates to an electron beam mask, a production method thereof, and an exposure method and in particular, to an electron beam mask used in an electron beam batch projection exposure step, a production method thereof, and an exposure method.

2. Description of the Related Art

Conventionally, the electron beam lithography technique utilizing the excellent resolution of the electron beam (hereinafter, may be referred to as EB) has been implemented in practice for directly drawing a design pattern having an extremely small design line width and has been used mainly for a preparatory test production.

Although this electron beam direct drawing technique is capable of drawing a fine design pattern, it has a disadvantage that the throughput is lowered when a pattern area is increased while using the point beam method, i.e., an electron beam direct drawing apparatus scans a point beam for drawing along a single line.

In order to eliminate this disadvantage, a variable rectangular type of the electron beam direct drawing apparatus has been developed.

This electron beam direct drawing apparatus of the variable rectangular type applies an electron beam having a properly widened area into a rectangular aperture and polarizes the beam into another rectangular aperture provided below, thereby creating rectangular beams of various sizes for drawing. This can significantly improve the throughput as compared to the EB direct drawing apparatus of the point beam type.

However, this EB direct drawing apparatus of the variable rectangular type improving the throughput as compared to the apparatus of the point beam type has a disadvantage that its throughput is lowered when drawing a complicated device pattern having special end rules, increasing the number of shots.

In order to solve this disadvantage and increase the throughput, a partial batch exposure method has been developed for repeatedly performing a drawing using a mask in which a part of a device pattern repeated many times is created. Furthermore, an entire batch exposure method has been developed for drawing an entire design all at once using a mask in which the entire design is created.

These batch exposure methods enable to utilize the high resolution of the electron beam and to obtain an exposure (drawing) having an excellent throughput.

In these batch exposure methods, a stencil mask 20 shown in FIG. 13 is normally used as the EB exposure mask (hereinafter, may be referred to as an electron beam mask) required for drawing a device pattern

The stencil mask 20 includes a stencil portion 21 having an aperture 22 according to a design pattern based on a design pattern, a junction portion 23 made from SiO₂, and a column 24 made from 24 and protrudes from the junction portion 23.

Here, the aperture 22 of the stencil portion 21 is formed by patterning through etching of a Si thin film according to the design pattern. Electrons of the electron beam can pass through only the aperture 22 and cannot pass through the stencil portion 21 (portion other than the aperture 22), thereby assuring a contrast.

However, the batch exposure method has a problem that an electron beam mask cannot be produced for a particular device pattern (a doughnut pattern) as shown in FIG. 14. A pattern region 25 of a device pattern has an unexposed portion 27 surrounded by an exposed portion 26 of a doughnut shape. In this case, it is impossible to create the portion 27 of the disc pattern because it is not supported by any portion.

Moreover, the batch exposure method has a problem that a particular device pattern (a leaf pattern) can be produced but cannot be used in an actual production because of the insufficient strength.

FIG. 15 shows such a pattern. A pattern region 25 includes an unexposed portion 27 of leaf shape surrounded by an exposed portion 26 of a quasi-doughnut shape. The unexposed portion 27 is supported only via a holding portion (bridge) 28 at one side and the strength to support the unexposed portion 27 is insufficient. Accordingly, the unexposed portion 27 easily causes deformation of the pattern or may drop and such a pattern cannot be used in an actual production.

Various techniques have been suggested to solve these problems.

As a first technique, a membrane mask 29 as shown in FIG. 16 has been suggested. This membrane mask 29 includes a support film 30 made from SiN which transmits electrons of an electron beam. On this support film 30, a metal layer 31a made from Cr and a metal layer 31b made from W are successively layered. This multi-layered film has an aperture 22 according to a design pattern.

However, this membrane mask 29 has various problems. Since the support film 30 is very thin, a stress of a heavy metal may cause a pattern position displacement. Moreover, since the support film 30 is formed to cover the entire region transmitting an electron beam and the entire region not transmitting the electron beam, a charge-up is easily caused.

Moreover, the material of the support film 30 is limited to those having a sufficient strength to support a metal layer surrounded by a doughnut shape. That is, the selection range of the material is small.

That is, even the membrane mask cannot solve the doughnut and the leaf problems completely.

As a second technique, a stencil mask 20 of a leaf shape has been suggested as shown in FIG. 17. In this case, a rectangular unexposed portion 27 is supported by a plurality of holder portions 28.

However, this solution may modify the pattern configuration, disabling to obtain an accurate fine exposure.

As a third technique, a complementary mask (not depicted) has been suggested in J. Vac. Sci. Techol. B 11 (1933), p2400, wherein a device pattern based on a design pattern is divided into a plurality of masks.

When using this complementary mask, a pattern transfer requires a repeated EB application, lowering the throughput.

### SUMMARY OF THE INVENTION

It is therefore an object of the present invention to provide an electron beam mask which eliminates the doughnut problem and the leaf problem in the batch exposure method, a production method thereof, and an exposure method capable of performing a high-quality exposure using the electron beam mask.

In order to achieve the aforementioned object, the present invention provides an electron beam mask having a plurality of apertures according to a predetermined design pattern for use in a batch projection exposure by an electron beam, wherein at least one of the apertures which requires reinforcement is filled with a thin

This configuration can improve the strength of the electron beam mask, even when an aperture of the disc pattern according to the design pattern weakens the strength of the electron beam mask. Accordingly, it is possible to maintain a high dimensional accuracy of the disc pattern.

The at least one aperture may have a shape surrounding an isolated stencil portion entirely like a doughnut or almost entirely like a bridged doughnut, i.e., having a bridge connecting the isolated stencil portion to the other stencil portion.

This configuration can solve the problem of a doughnut pattern and a bridged doughnut pattern (leaf patter) involved in the disc pattern according to the design pattern, enabling to provide an electron beam mask not affecting the exposure accuracy.

The material constituting the thin film may be carbon, silicon carbide, or silicon nitride compound.

By using the materials which are normally used in a production procedure, it is possible to produce an electron beam mask easily and at a low cost.

The stencil portion shading the electron beam may be made from a metal.

This can effectively suppress a contrast insufficiency due to electron scattering at the boundary between the stencil portion and the thin film.

Another aspect of the present invention provides an electron beam mask production method for producing an electron beam mask having a plurality of apertures according to a predetermined design pattern for use in a batch projection exposure by an electron beam, the method comprising steps of: forming an oxide film below at least one of the apertures which requires reinforcement; forming in the at least one aperture a thin film that transmits the electron beam; and removing the oxide film after formation of the thin film.

When the oxide film is provided, it can stop sputtered atoms during formation of the thin film, thereby enabling to produce a high-quality electron beam mask.

The thin film formation step may include patterning of the thin film with a surface pattern greater than the shape of the at least one aperture.

This assures the thin film to fill the aperture and increase the physical junction strength between the thin film and the aperture.

The electron beam mask production method may further comprise prior to the thin film formation step, a step for detecting the aperture requiring reinforcement according to the design pattern, i.e., the aperture to be filled with the thin film such as those having a doughnut shape or a bridged doughnut (leaf) shape.

This enables to solve the doughnut pattern problem and the leaf pattern problem. Since the thin film is formed selectively in the apertures requiring reinforcement such as those having the doughnut or bridged doughnut shape, it is possible to eliminate the problem of charge-up during exposure.

Still another aspect of the present invention provides a batch projection exposure method using an electron beam and the aforementioned electron beam mask.

Use of the electron beam mask of the present invention enables to perform an exposure having a high accuracy and an excellent throughput.

### BRIEF DESCRIPTION OF THE DRAWINGS

FIG. 1 is an enlarged cross sectional view of an essential portion of an electron beam mask according to a first embodiment of the present invention.

FIG. 2 is an enlarged plan view of an essential portion of the electron beam mask according to the first embodiment of the present invention.

FIG. 3 is a flowchart showing a production method of an electron beam mask according to a second embodiment.

FIG. 4 shows an enlarged output of an essential portion of a mask pattern data. FIG. 4 (a) shows an output associated with a doughnut pattern, and FIG. 4 (b) shows an output associated with a leaf pattern.

FIG. 5 shows an enlarged output of a surface pattern of a positive type resist. FIG. 5 (a) is an enlarged plan view of a doughnut pattern, and FIG. 5 (b) is an enlarged plan view of a leaf pattern.

FIG. 6 is a schematic enlarged cross sectional view of an essential portion of an electron beam mask upon completion of a first step of an electron beam mask production method according to the second embodiment.

FIG. 7 is a schematic enlarged cross sectional view of the essential portion of the electron beam mask upon completion of a second step of the electron beam mask production method according to the second embodiment.

FIG. 8 is a schematic enlarged cross sectional view of the essential portion of the electron beam mask upon completion of a third step of the electron beam mask production method according to the second embodiment.

FIG. 9 is a schematic enlarged cross sectional view of the essential portion of the electron beam mask upon completion of a fourth step of the electron beam mask production method according to the second embodiment.

FIG. 10 is a schematic enlarged cross sectional view of the essential portion of the electron beam mask upon completion of a fifth step of the electron beam mask production method according to the second embodiment.

FIG. 11 is a schematic enlarged cross sectional view of the essential portion of the electron beam mask upon completion of a sixth step of the electron beam mask production method according to the second embodiment.

FIG. 12 is a schematic enlarged cross sectional view of the essential portion of the electron beam mask upon completion of the last step of the electron beam mask production method according to the second embodiment.

FIG. 13 is an enlarged schematic cross sectional view of an essential portion of a stencil mask as a conventional example.

FIG. 14 is an enlarged schematic plan view of an essential portion of a CAD pattern having a doughnut pattern.

FIG. 15 is an enlarged schematic plan view of an essential portion of a CAD pattern having a leaf pattern.

FIG. 16 is an enlarged cross sectional view of an essential portion of a conventional membrane mask used for coping with the doughnut pattern.

FIG. 17 is an enlarged plan top view of a stencil mask having a holding portion conventionally used to cope with the doughnut pattern.

### DESCRIPTION OF THE PREFERRED EMBODIMENTS

Description will now be directed to an electron beam mask, a production method thereof, and an exposure method according to embodiments of the present invention with reference to the attached drawings.

### EMBODIMENT 1

FIG. 1 is an enlarged cross sectional view showing an essential portion of an electron beam mask according to a first embodiment.

In this figure, the electron beam mask 1 includes a stencil portion 2 having an opening portion 4 of a doughnut shape, a thin film (hereinafter, referred to as a membrane) 5 buried in the opening portion 4 so as to surround an unexposed portion 3, and columns protruding from the stencil.

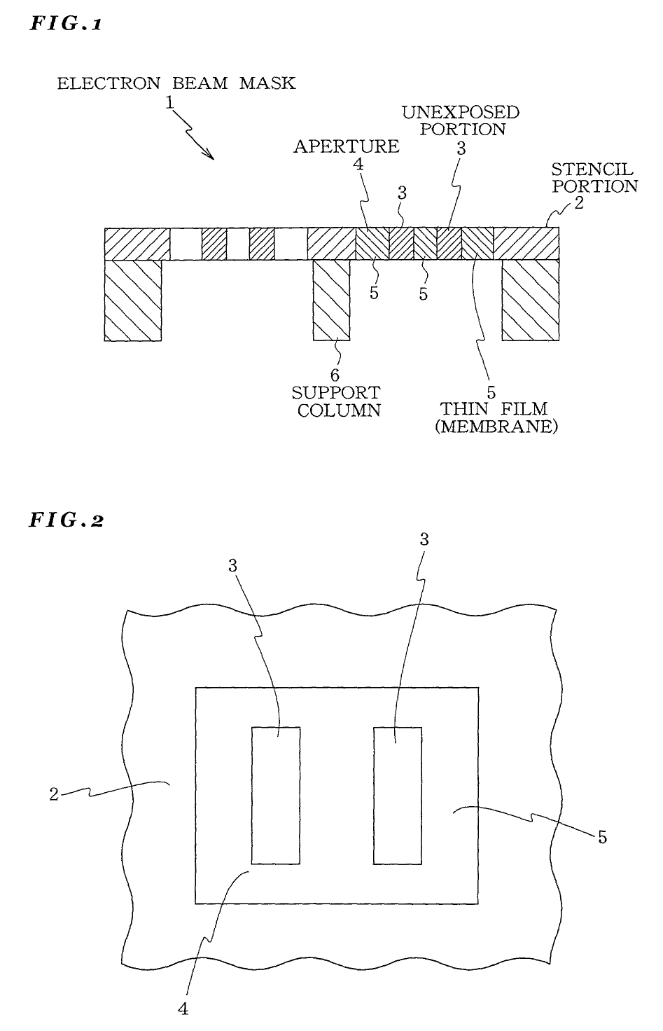

Here, as shown in FIG. 2, the unexposed portion 3 surrounded by the opening portion 4 of a doughnut shape is supported by the membrane 5 buried into the opening portion 4.

Moreover, the membrane 5 is made from a material having a low probability of the electron beam scattering, so that the electron beam can pass through the membrane 5 with a small scattering angle.

Here, as a preferable material of the membrane 5, there can be exemplified carbon (C), silicon carbide (SiC) compound, or silicon nitride (SiN) compound. These materials are normally used in the semiconductor production and require no special handling, enabling to produce the electron beam mask 1 at a low cost.

Furthermore, the stencil portion 2 is preferably made from a metal which can shade the electron beam completely, enabling to obtain a clear contrast of the boundary between the membrane 5 and the stencil portion 2.

Thus, the electron beam mask 1 according to the first embodiment includes the membrane 5 buried only in the opening portion of the stencil for solving the doughnut and the leaf problems. As compared to the conventional example including a membrane arranged over the entire stencil, it is possible to suppress the charge-up problem when solving the doughnut problem and the leaf problem.

Furthermore, by forming the membrane 5 in the opening portions requiring an especially high accuracy or requiring n additional strength in a design pattern, it is possible to improve the strength of the stencil portion 2 and maintain the device pattern dimensional accuracy.

### EMBODIMENT 2

Next, explanation will be given on an electron beam mask production method according to a second embodiment of the present invention.

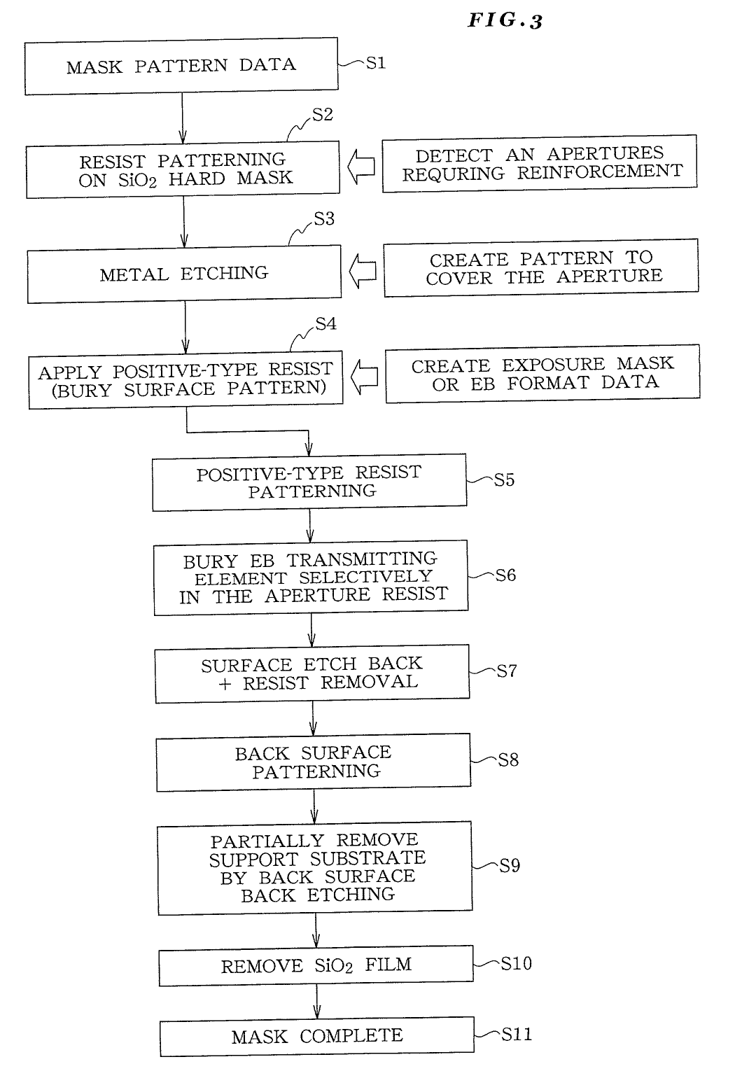

FIG. 3 is a flowchart showing the electron beam mask production method according to the second embodiment.

The flowchart shows a production method including extraction of the doughnut problem and the leaf problem.

In step S1, a mask pattern data based on a design pattern indispensable for producing an electron beam mask is entered.

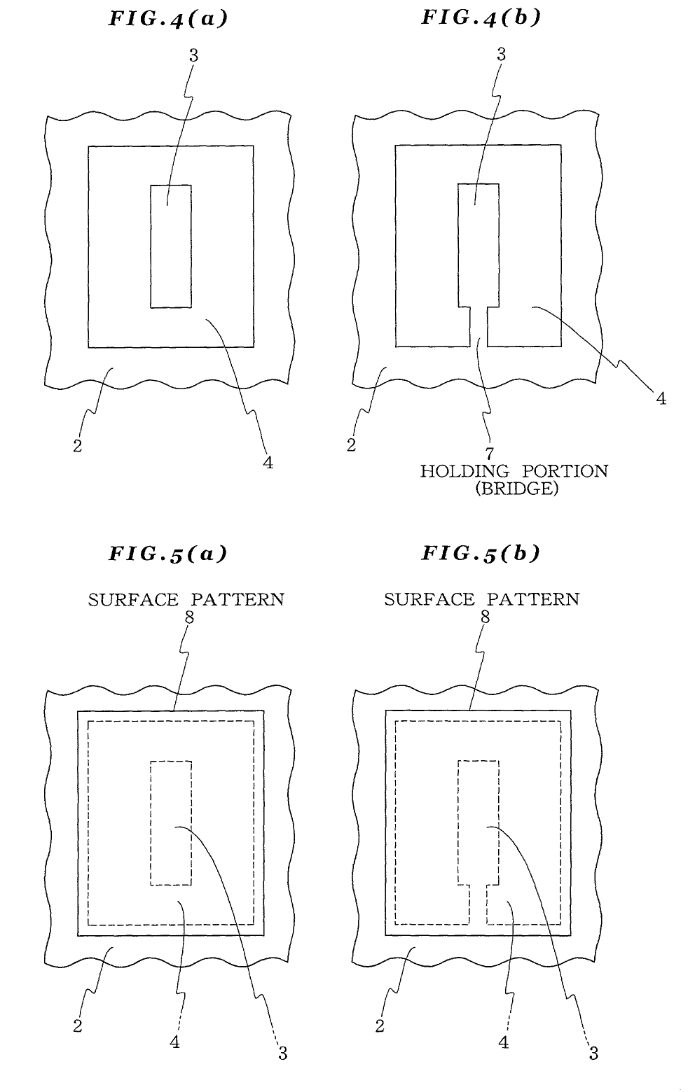

Subsequently, in step S2, a doughnut problem pattern and a leaf problem pattern as shown in FIG. 4 are detected from the mask pattern data. Here, it is preferable to prepare a software for detecting these patterns and detection is performed by a computer, thereby reducing the design time.

It should be noted that the patterns shown in FIG. 4 are only examples and the doughnut problem pattern and the leaf problem pattern are not to be limited to these.

According to the detected pattern, a resist patterning is performed on a hard mask made from SiO₂.

Next, in step S3, a pattern is creased to cover an opening portion associated with the doughnut pattern and the leaf pattern, and a metal etching is performed according to the pattern covering the opening portion 4.

Here, the unexposed portion associated with the doughnut problem and the leaf problem remains without being etched.

Next, in step S4, the pattern covering the opening portion is used to create a data for creating an exposure mask to be used in the DUV drawing or to create a EB format data inherent to an EB direct drawing apparatus used for the EB exposure.

By using this exposure mask or the EB exposure format data, a positive type resist is buried to form a surface pattern.

That is, as shown in FIG. 5, the positive type resist is buried with a surface pattern 8 greater than the opening configuration of the opening 4 of the doughnut and the leaf problem pattern.

Next, in step S5, the doughnut problem pattern and the leaf problem pattern are patterned into the positive type resist.

That is, in order to reinforce the opening portion 4 surrounding the unexposed portion 3, the range of the surface pattern 8 is patterned.

This assures to bury a thin film in the opening portion and increases the physical junction strength between the thin film and the opening portion.

Next, in step S6, a material transmitting an electron beam is selectively buried into the resist of the opening portion.

Thus, an electron beam can transmit the resist, i.e., the membrane 5.

Next, in step S7, the surface etching and the resist removal are performed.

By this, the upper surface of the membrane 5 becomes flat with the adjacent stencil portion 2 without any stepped portion.

Next, in step S8, a back surface patterning is performed. Furthermore, in step S9, a back surface etching is performed to remove a part of the Si wafer so as to form the column 6.

Next, in step S10, the SiO₂ film is removed and in step S11, an electron beam mask is complete.

Thus, the electron beam mask production method according to the second embodiment enables to produce an electron beam mask capable of eliminating the doughnut problem and the leaf problem. That is, it is possible to suppress the charge-up problem as compared to a conventional example which provides a holding film over the entire stencil.

Next, a production example according to this production method will be explained with reference to the attached drawings.

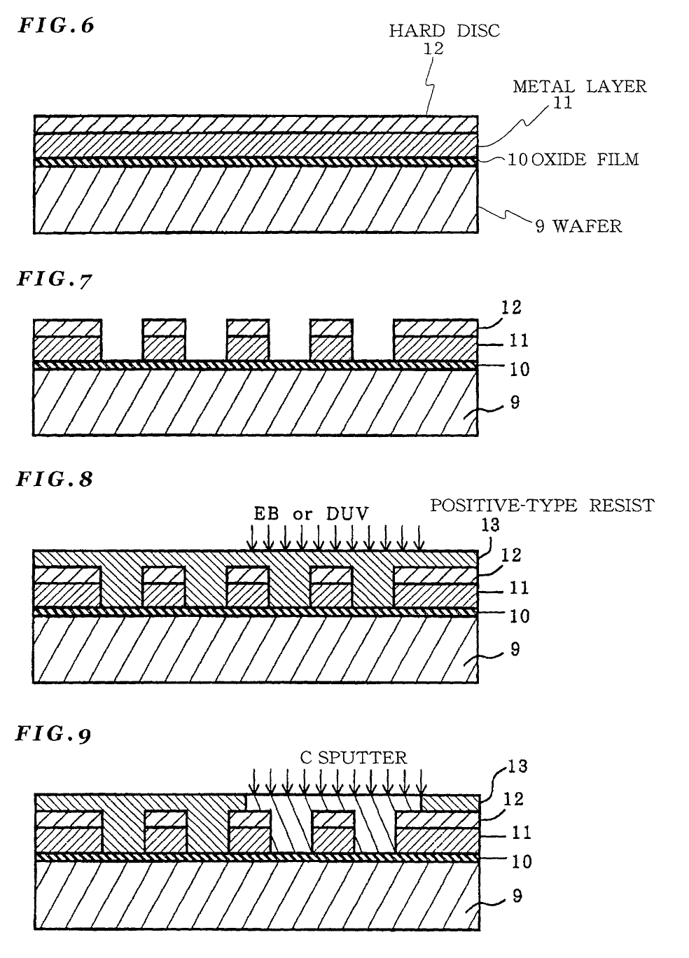

Firstly, a shown in FIG. 6, on the surface of a wafer 9 made from Si, an oxide film 10 (SiO₂), a metal layer 11, and a hard mask 12 made from a silicon oxide film (SiO₂) or a silicon nitride film (SiN) are successively layered.

Here, the outermost hard mask 12 is used when the resist selection ratio with respect to the metal etching (metal etching rate / resist etching rate) is low. Accordingly, the hard mask 12 need not be formed when the resist selection ratio in etching is high.

As a second step, as shown in FIG. 7, a resist is applied to form a master pattern. Using this resist as a mask, etching is performed to the silicon oxide film or the silicon nitride film on the surface. Then, the resist is removed and etching is performed to the metal layer from the side of the silicone surface.

This step corresponds to the steps S2 and S3 in FIG. 3.

Next, as a third step shown in FIG. 8, a positive type resist 13 is buried in the patterned metal layer 11 and a laser beam such as EB and DUV is selectively applied only to the doughnut pattern region and the leaf pattern region (the range of the surface pattern 8 shown in FIG. 5) which have been extracted by another software.

This step corresponds to steps S4 and S5 in FIG. 3.

Accordingly, when performing a development such as acid peel-off process, it is possible to dissolve the resist in the doughnut and the leaf pattern regions to selectively leave an open portion.

Next, as the fourth step shown in FIG. 9, a material (C) transmitting an electron beam is selectively applied by sputtering only to the doughnut and the leaf pattern regions.

This step corresponds to step S6 in FIG. 3.

The material buried here has a depth defined by the top surface of the oxide film 10.

Thus, it is possible to produce a high-quality electron beam mask where the C sputter is not scattered.

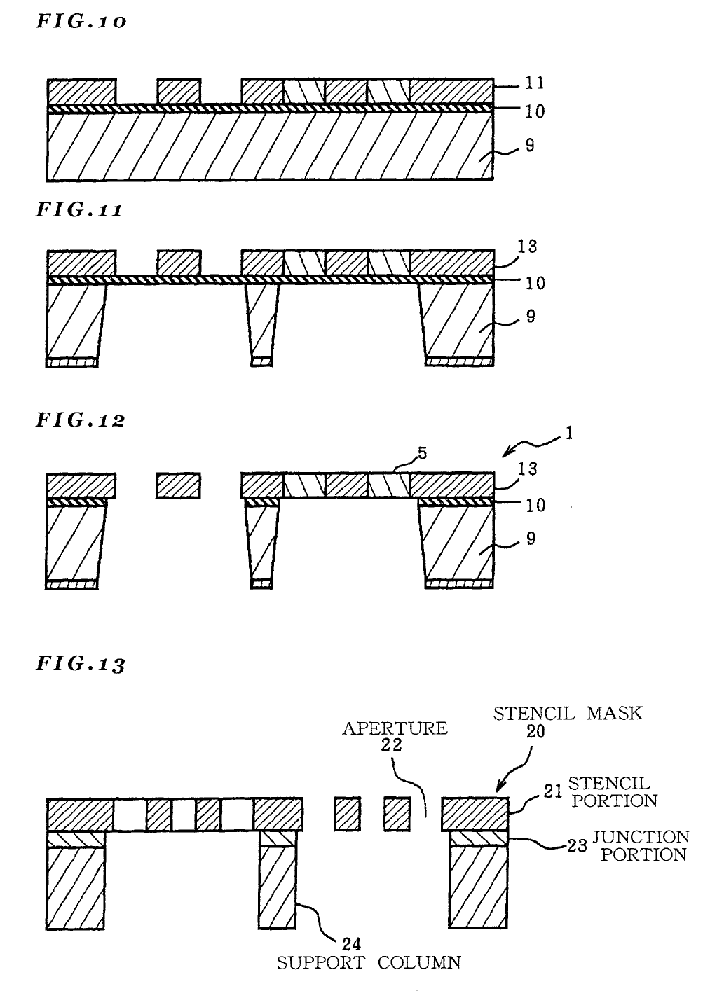

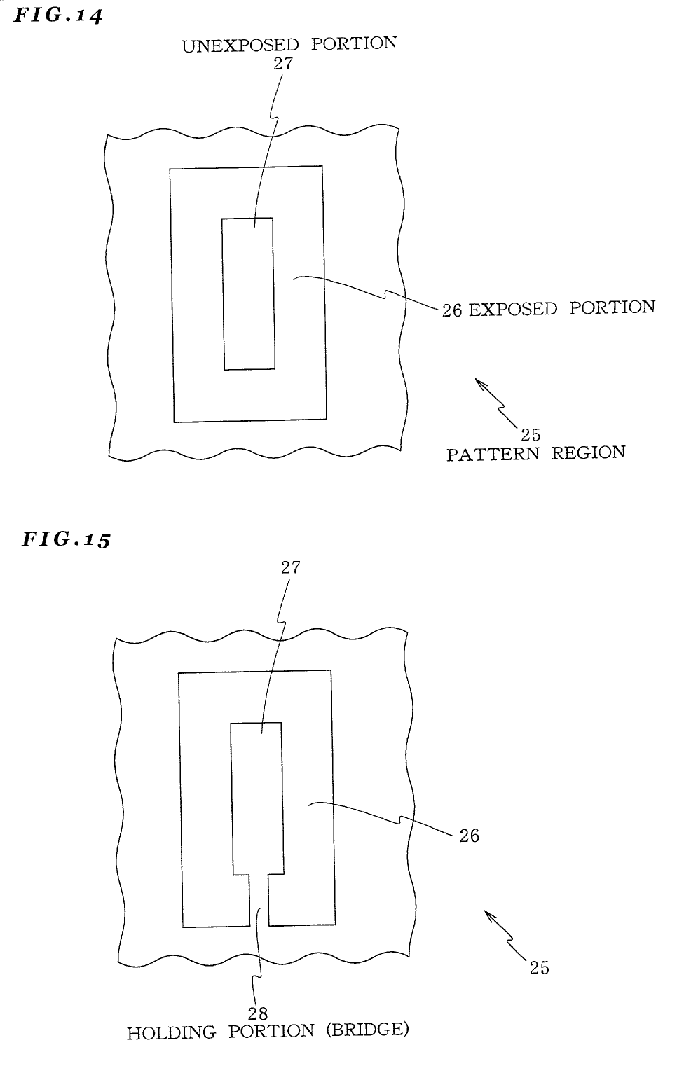

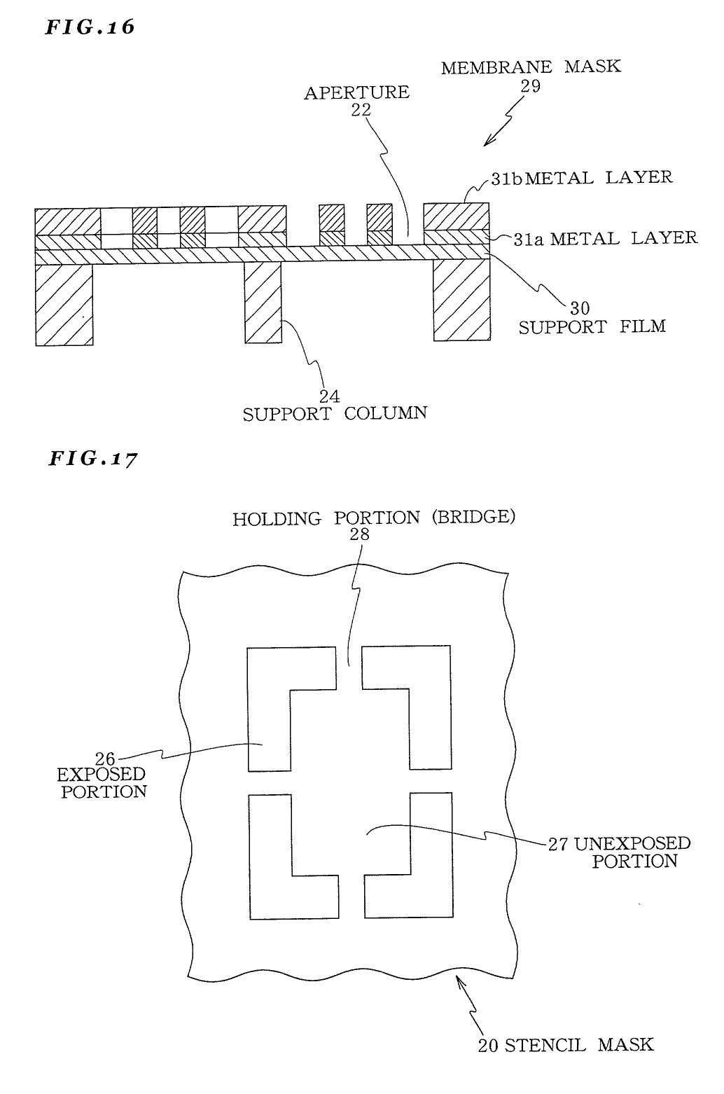

Next, as the fifth step shown in FIG. 10, etch back or the CMP method (chemical/mechanical polishing method) is used to remove the hard mask 12 and a portion of the material transmitting the electron beam protruding above the metal layer 11. Moreover, the remaining positive type resist 13 is removed by the acid peel-off or the like.

This step corresponds to step S7 in FIG. 3.

Next, as the sixth step shown in FIG. 11, the back surface patterning and wet or dry etching from the back surface are performed to etch the wafer 9 as the support substrate.

This step corresponds to steps S8 and S9 in FIG. 3.

Lastly, as shown in FIG. 12, the oxide film 10 (SiO₂) is removed to complete the electron beam mask.

This step corresponds to steps S10 and S11 in FIG. 3.

Thus, according to the electron beam mask production method of the second embodiment, the electron beam mask can be produced.

It should be noted that in the aforementioned example of the production, when patterning a doughnut pattern region after etching of the metal layer, a region other than the doughnut pattern region is protected by the positive type resist 13. The resist 13 covering the doughnut pattern region lowers its molecular weight when subjected to the EB or DUV and can be dissolved when immersed in a developing liquid.

In the doughnut pattern region, the resist molecules are hardened to prevent intrusion of the developing liquid and the electron beam transmitting material sputtered to form a film.

The second embodiment may be modified in various ways. For example, upon completion of the etching of the metal layer 11, the entire pattern region can be protected by a resin, which is then coated with a resist. By patterning this resist, it is possible to obtain an open doughnut pattern region. In this portion alone, the resin protecting the pattern is removed by a chemical process. Thus, it is possible to prevent intrusion of the electron beam transmitting material.

### EMBODIMENT 3

Next, explanation will be given on an exposure method as a third embodiment of the present invention using the electron beam mask according to the present invention.

The present invention provides an advantage as an exposure method using the electron beam mask, enabling exposure of a fine pattern with a high accuracy which is required to reduce the size of and improve a performance of a semiconductor device.

More specifically, this requirement can be fulfilled because no holding portion is needed in the doughnut pattern.

As for the leaf pattern, it is possible to prevent deformation or damage of the electron beam mask and to obtain a high-quality exposure with a high accuracy.

As has been described above, the present invention provides an electron beam mask capable of solving the doughnut pattern problem and the leaf pattern problem.

Moreover, in this electron beam mask, by selecting the thin film (membrane) material and the mask stencil material in such a way that a difference is caused in the electron scattering degree, it is possible to obtain an exposure of a clear contrast.

Furthermore, by using a limit aperture at a crossover, it is possible to prevent electrons scattered with a large angle, thereby clearing the contrast.

Moreover, according to the electron beam mask production method of the present invention, the electron beam transmitting material is selectively buried in the doughnut or leaf pattern, thereby solving the doughnut and leaf pattern problems.

Moreover, since there is no need of forming a thin film of the light transmitting material having a large area, the material does not necessarily have a particular physical strength, thereby increasing the material selection range, enabling to prevent an electron beam mask as a reasonable cost.

Moreover, apertures other than the doughnut pattern or the leaf pattern are not covered by the thin film and it is possible to effectively suppress generation of the charge-up.

The exposure method of the present invention uses the electron beam mask according to the present invention in which an aperture of the doughnut or leaf pattern is filled with the electron beam transmitting material to make the stencil portion flat, preventing lowering of the mask strength due to the doughnut or the leaf pattern. Accordingly, there is no danger of deterioration of the exposure accuracy as the time lapses and it is possible to obtain a high-quality exposure.

The invention may be embodied in other specific forms without departing from the spirit or essential characteristic thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 11-368719 (Filed on Dec. 27^{th}, 1999) including specification, claims, drawings and summary are incorporated herein by reference in its entirety.

What is claimed is:

1. An electron beam mask having a plurality of apertures according to a predetermined design pattern for use in a batch projection exposure by an electron beam,
wherein at least one of the apertures which requires reinforcement is filled with a thin film made from a material transmitting the electron beam.

2. An electron beam mask as claimed in claim 1, wherein the at least one aperture has a shape surrounding an isolated stencil portion entirely like a doughnut or almost entirely like a bridged doughnut, i.e., having a bridge connecting the isolated stencil portion to the other stencil portion.

3. An electron beam mask as claimed in claim 1, wherein the material constituting the thin film is carbon, silicon carbide, or silicon nitride compound.

4. An electron beam mask as claimed in claim 2, wherein the material constituting the thin film is carbon, silicon carbide, or silicon nitride compound.

5. An electron beam mask as claimed in claim 1, wherein the stencil portion shading the electron beam is made from a metal.

6. An electron beam mask as claimed in claim 2, wherein the stencil portion shading the electron beam is made from a metal.

7. An electron beam mask as claimed in claim 3, wherein the stencil portion shading the electron beam is made from a metal.

8. An electron beam mask as claimed in claim 4, wherein the stencil portion shading the electron beam is made from a metal.

9. An electron beam mask production method for producing an electron beam mask having a plurality of apertures according to a predetermined design pattern for use in a batch projection exposure by an electron beam, the method comprising steps of:
forming an oxide film below at least one of the apertures which requires reinforcement;
forming in the at least one aperture a thin film that transmits the electron beam; and
removing the oxide film after formation of the thin film.

10. An electron beam mask production method as claimed in claim 9, wherein the thin film formation step includes patterning of the thin film with a surface pattern greater than the shape of the at least one aperture.

11. An electron beam mask production method as claimed in claim 9, the method further comprises prior to the thin film formation step,
a step for detecting the aperture requiring reinforcement according to the design pattern, i.e., the aperture to be filled with the thin film.

12. An electron beam mask production method as claimed in claim 10, the method further comprises prior to the thin film formation step,
a step for detecting the aperture requiring reinforcement according to the design pattern, i.e., the aperture to be filled with the thin film.

13. A batch projection exposure method using an electron beam and an electron beam mask, wherein the electron beam mask has the configuration defined in claim 1.

14. A batch projection exposure method using an electron beam and an electron beam mask, wherein the electron beam mask has the configuration defined in claim 2.

15. A batch projection exposure method using an electron beam and an electron beam mask, wherein the electron beam mask has the configuration defined in claim 3.

16. A batch projection exposure method using an electron beam and an electron beam mask, wherein the electron beam mask has the configuration defined in claim 4.

17. A batch projection exposure method using an electron beam and an electron beam mask, wherein the electron beam mask has the configuration defined in claim 5.

18. A batch projection exposure method using an electron beam and an electron beam mask, wherein the electron beam mask has the configuration defined in claim 6.

19. A batch projection exposure method using an electron beam and an electron beam mask, wherein the electron beam mask has the configuration defined in claim 7.

20. A batch projection exposure method using an electron beam and an electron beam mask, wherein the electron beam mask has the configuration defined in claim 8.
